(19) United States
(12) Patent Application Publication
(10) Pub. No.: US 2026/0149434 A1
(43) Pub. Date: May 28, 2026

(54) OUT-OF-AUDIO SWITCHING FREQUENCY CONTROL

(71) Applicant: TEXAS INSTRUMENTS INCORPORATED, Dallas, TX (US)

(72) Inventor: Mufeng Xiong, Tianjin (CN)

(21) Appl. No.: 18/956,092

(22) Filed: Nov. 22, 2024

(51) Int. Cl. H03K 3/037; H02M 3/158

(52) U.S. Cl. CPC H03K 3/0375; H02M 3/158

(57) ABSTRACT

An apparatus includes a logic circuit having a clock input, a first logic circuit control output, and a second logic circuit control output. A clock generation circuit has a first clock control input, a second clock control input, and a clock output. The clock output is coupled to the clock input. An off-timer circuit has an off-timer output. A comparator has a comparator output. An out-of-audio (OOA) circuit has a first OOA input, a second OOA input, a third OOA input, a first OOA output, and a second OOA output. The first OOA input is coupled to the comparator output. The second OOA input is coupled to the clock output. The third OOA input is coupled to the off-timer output. The first OOA output is coupled to the first clock control input. The second OOA output is coupled to the second clock control input.

### BACKGROUND

A power converter converts an input voltage into a higher or lower output voltage. One type of power converter is a switching converter. A switching converter includes one or more switches (e.g., transistors) that are turned on and off at a switching frequency. The switching frequency of a switching converter may be a fixed frequency or may vary based on the operation condition of the converter.

### SUMMARY

In one example, an apparatus includes a logic circuit having a clock input, a first logic circuit control output, and a second logic circuit control output. A clock generation circuit has a first clock control input, a second clock control input, and a clock output. The clock output is coupled to the clock input. An off-timer circuit has an off-timer output. A comparator has a comparator output. An out-of-audio (OOA) circuit has a first OOA input, a second OOA input, a third OOA input, a first OOA output, and a second OOA output. The first OOA input is coupled to the comparator output. The second OOA input is coupled to the clock output. The third OOA input is coupled to the off-timer output. The first OOA output is coupled to the first clock control input. The second OOA output is coupled to the second clock control input.

In another example, an apparatus includes a logic circuit having a clock input, a first logic circuit control output, and a second logic circuit control output. A clock generation circuit has a clock output, a first clock control input, and a second clock control input the clock output coupled to the clock input. An off-timer circuit has an off-timer output. A comparator has a comparator output. An OOA circuit is coupled to the comparator output, the clock output, the first clock control input, the second clock control input, and the off-timer output. The OOA circuit is configured to start a timer based on a comparator signal from the comparator output and to cause the logic circuit to initiate a switching cycle outside an audible frequency range, wherein initiation the switching cycle is based on expiration of the timer.

In yet another example, a power converter includes a power stage having a first power stage input and a second power stage input. A logic circuit has a clock input, a first logic circuit control output, and a second logic circuit control output. The first logic circuit control output is coupled to the first power stage input, and the second logic circuit control output is coupled to the second power stage input. A clock generation circuit has a clock output, a first clock control input, and a second clock control input the clock output coupled to the clock input. An off-timer circuit has an off-timer output. A comparator has a comparator output. AN OOA circuit is coupled to the comparator output, the clock output, the first clock control input, the second clock control input, and the off-timer output. The OOA circuit is configured to start an OOA circuit timer based on a comparator signal from the comparator output and to cause the logic circuit to initiate a switching cycle upon expiration of the OOA circuit timer.

### BRIEF DESCRIPTION OF THE DRAWINGS

FIGS. 1A and 1B (collectively, FIG. 1) are a schematic diagram of a power converter which includes an out-of-audio circuit, in an example.

FIG. 2 is a flow chart also illustrating the operation of the out-of-audio circuit of FIG. 1, in an example.

FIG. 3 are waveforms illustrating the operation of the out-of-audio circuit of FIG. 1, in an example.

### DETAILED DESCRIPTION

The same reference numbers or other reference designators are used in the drawings to designate the same or similar (either by function and/or structure) features.

As described above, the switching frequency of a switching converter may vary based on the operating condition of the converter. For example, at low load conditions, the switching converter may reduce its switching frequency to maintain the output voltage at its target (regulated) level. If the switching frequency were to be reduced below the upper frequency of human hearing, the switching converter may produce an audible tone at the switching frequency. For example, an output capacitor of the switching converter may vibrate at the switching frequency, and the vibrating capacitor may be audible to humans, which is undesirable. The examples described herein pertain to an out-of-audio circuit included within or coupled to a switching converter that ensures the switching frequency of the converter remains above the upper frequency limit of human hearing (e.g., 20 KHz, 25 KHz) while reducing the risk of the converter falling out of regulation.

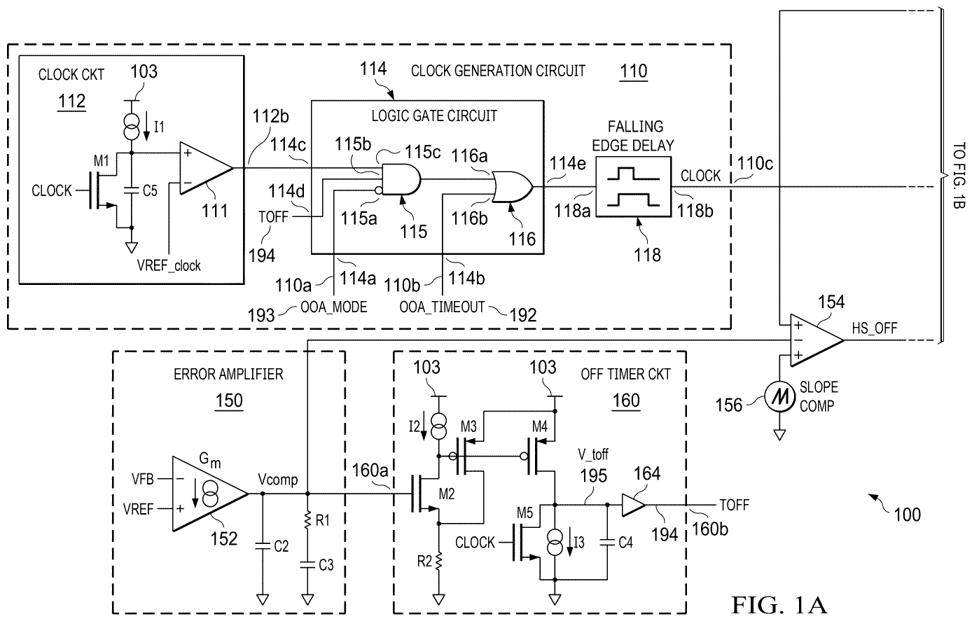

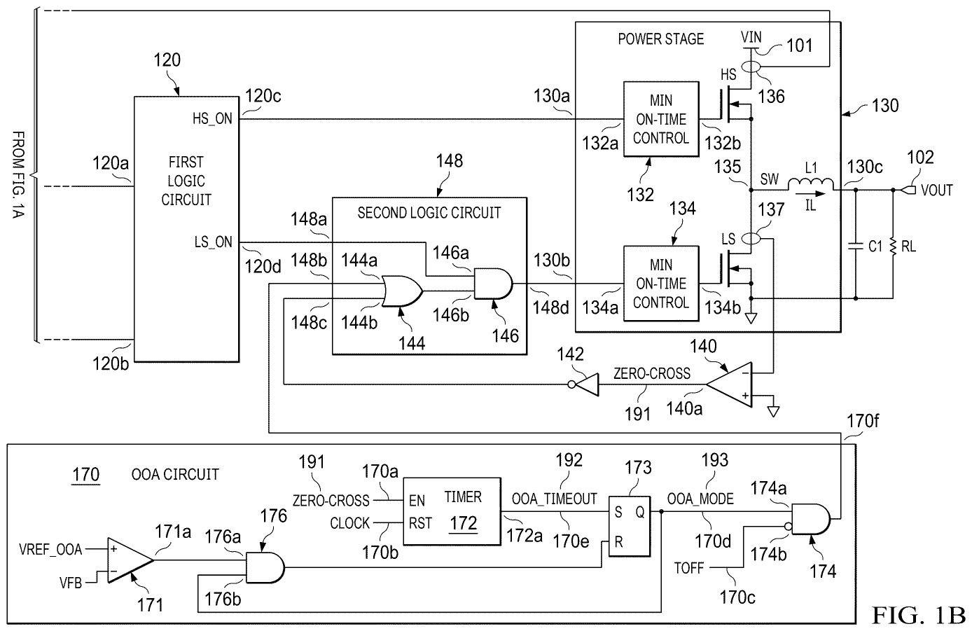

FIG. 1 is a schematic diagram of a power converter 100, in an example. Power converter 100 includes a clock generation circuit 110, a first logic circuit 120, a power stage 130, a comparator 140, an inverter 142, a second logic circuit 148, an error amplifier 150, a comparator 154, a slope compensator 156, an off-timer circuit 160, and an out-of-audio (OOA) circuit 170. Power converter 100 has an input voltage terminal 101, to which an input voltage VIN can be supplied, and an output voltage terminal 102, which produces the output voltage VOUT. Power stage 130 has power stage inputs 130a and 130b and a power stage output 130c. Power stage output 130c is coupled to the output voltage terminal 102. A capacitor C1 is coupled between the power stage output 130c and ground. Load resistance RL represents a load powered by power converter 100.

Other than load resistance RL, in one example, the other components shown in FIG. 1 are fabricated on the same integrated circuit (IC) or the same module (e.g., a multi-die module), and such IC or module is the power converter 100. In another example, clock generation circuit 110, first logic circuit 120, comparator 140, inverter 142, second logic circuit 148, error amplifier 150, comparator 154, slope compensator 156, off-timer circuit 160, and OOA circuit 170 (but not power stage 130 and capacitor C1) are fabricated on the same IC, and power stage 130 and capacitor C1 are external to that IC. In this latter example, the IC containing clock generation circuit 110, first logic circuit 120, comparator 140, inverter 142, second logic circuit 148, error amplifier 150, comparator 154, slope compensator 156, off-timer circuit 160, and OOA circuit 170 is an IC containing a controller for a power converter.

Clock generation circuit 110 has clock control inputs 110a and 110b and a clock output terminal 110c. First logic circuit 120 has a clock input 120a, logic circuit input 120b and logic circuit control outputs 120c and 120d. Second logic circuit 148 has logic circuit control inputs 148a, 148b, and 148c and an output 148d. Off-timer circuit 160 has an off-timer input 160a and an off-timer output 160b. OOA circuit 170 has OOA inputs 170a, 170b, and 170c and OOA outputs 170d, 170e, and 170f.

Clock output terminal 110c from clock generation circuit 110 is coupled to clock input 120a of first logic circuit 120. The output of comparator 154 is coupled to logic circuit input 120b. The logic circuit control output 120c is coupled to the power stage input 130a. The logic circuit control output 120d is coupled to the logic circuit control input 148b. The OOA output 170f is coupled to the logic circuit control input 148c. The output 148d of the second logic circuit 148 is coupled to the power stage input 130b.

Power stage 130 includes a high side (HS) switch coupled in series with a low side (LS) switch between the input voltage terminal 101 and ground. Each of the HS and LS switches are transistors in the example of FIG. 1, for example, field effect transistors. The connection between the transistors is a switching terminal SW 135 and is coupled to one terminal of an inductor L1. The current through inductor L1 is current IL. The other terminal of the inductor is coupled to the output voltage terminal 102 and to capacitor C1. The power converter 100 in FIG. 1 is an example of a buck converter but power converter 100 can be other types of switching power converters. Power stage 130 also has a minimum on-time control circuit 132 for the HS switch and a minimum on-time control circuit 134 for the LS switch. Minimum on-time control circuit 132 has an input 132a coupled to power stage input 130a and has an output 132b coupled to a control input (e.g., a gate) of the HS switch. Similarly, minimum on-time control circuit 134 has an input 134a coupled to power stage input 130b and has an output 134b coupled to a control input (e.g., a gate) of the LS switch. A current sense circuit 136 is coupled to the HS switch to generate a signal indicative of (e.g., proportional to) the current flowing through the HS switch when the HS switch is closed. A current sense circuit 137 is coupled to the LS switch to generate a signal indicative of (e.g., proportional to) the current flowing through the LS switch when the LS switch is closed.

The output of current sense circuit 137 is coupled to the negative (−) input of comparator 140. The positive (+) input of comparator 140 is coupled to ground. The output 140a of comparator 140 is coupled to the input of inverter 142, and the output of inverter 142 is coupled to the logic circuit control input 148c. The output 170f of OOA circuit 170 is coupled to the logic circuit control input 148b. The OOA outputs 170d and 170e of OOA circuit 170 are coupled to the clock control inputs 110a and 110b, respectively, of clock generation circuit 110. OOA output 170d provides a OOA_MODE signal 193 and OOA output 170e provides a signal OOA_TIMEOUT 192.

Error amplifier 150 has inputs that receive a feedback voltage VFB, derived from the output voltage VOUT, for example, by way of resistor divider, and a reference voltage VREF. The output of error amplifier 150 provides a signal VCOMP. The output of error amplifier 150 is coupled to the off-timer input 160a and to a negative input of comparator 154. The off-timer output 160b provides a Toff signal 194 and is coupled to the OOA input 170c. Slope compensator 156 is coupled to a positive input of comparator 154 and the output of current sense circuit 136 is coupled to another positive input of comparator 154. The output of comparator 154 is coupled to logic circuit input 120b.

Clock generation circuit 110 includes a clock circuit 112, a logic circuit 114, and a falling edge delay circuit 118. Clock circuit 112 has an output 112b. Logic gate circuit 114 has inputs 114a, 114b, 114c, and 114d, and an output 114e. The output 112b of clock circuit 112 is coupled to the input 114c of logic gate circuit 114. The output 160b of off-timer circuit 160 is coupled to the input 114d of logic gate circuit 114. The clock control input 110a of clock generation circuit 110 is coupled to the input 114a of logic gate circuit 114. The clock control input 110b of clock generation circuit 110 is coupled to the input 114b of logic gate circuit 114. The output 114e of logic gate circuit 114 is coupled to an input 118a of falling edge delay circuit 118, and an output 118b of falling edge delay circuit 118 is coupled to the clock output terminal 110c of clock generation circuit 110. Falling edge delay circuit 118 delays the output falling edge by a predefined amount of time.

Clock circuit 112 includes a current source circuit I1, a transistor M1, a capacitor C5, and a comparator 111. Logic gate circuit 114 includes an AND gate 115 and an OR gate 116. The clock output terminal 110c of clock generation circuit 110 is coupled to the gate of transistor M1 and, accordingly, provides the clock signal Clock to the gate of transistor M1. The drain and source of transistor M1 are coupled across the terminals of capacitor C5. Current source circuit I1 is coupled between a voltage terminal 103 (e.g., an internally-generated voltage or an externally supplied voltage) and capacitor C5. When clock signal Clock becomes logic high, transistor M1 turns on, capacitor C5 discharges through transistor M5 to ground. Current source circuit I1 is coupled to capacitor C5. When clock signal Clock is logic low, transistor M1 turns off, and current from current source circuit I1 charges capacitor C5. Capacitor C5 is coupled to the positive input of comparator 111, and a reference voltage Vref_clock is provided to the comparator's negative input.

The output of comparator 111 is coupled to the output 112b of clock circuit 112 and to the input 114c of logic gate circuit 114. AND gate 115 has inputs 115a (an inverted input), 115b, and 115c. The inputs 115a, 115b, and 116c are coupled to the inputs 114a, 114d, and 114c, respectively, of logic gate circuit 114. The output of AND gate 115 is coupled to an input 116a of OR gate 116. The input 114b of logic gate circuit 114 is coupled to an input 116b of OR gate 116. The output of OR gate 116 is coupled to the output 114e of logic gate circuit 114 and to the input 118a of falling edge delay circuit 118. Falling edge delay circuit 118 generates the output signal Clock. The output 118b of falling edge delay circuit 118 is coupled to the clock output terminal 110c and to the clock input 120a of first logic circuit 120. Accordingly, in each clock cycle, current source circuit I1 charges capacitor C5 whose voltage will reach reference voltage Vref_clock thereby causing comparator 111 to generate a logic high signal at its output. Assuming signal Toff is logic high and OOA_MODE is logic low, a logic high for the output of comparator 111 causes clock signal Clock to become logic high. When clock signal Clock is becomes logic high, transistor M1 turns on thereby discharging capacitor C5 and resulting in the output of comparator 111 being logic low. Following a delay implemented by falling edge delay circuit 118, clock signal Clock also becomes logic low thereby turning off transistor M1. The process repeats. Clock signal Clock is a fixed frequency clock signal whose pulse width is approximately equal to the falling edge delay time implemented by falling edge delay circuit 118.

The output signal from comparator 111 is provided through AND gate 115 and OR gate 116 and through the falling edge delay circuit 118 to the clock input 120a of first logic circuit 120 if the logic state of the Toff signal 194 is high and the OOA_MODE signal 193 and the OOA_TIMEOUT signal 192 are logic low. Otherwise, if the Toff signal 194 is logic low and/or the OOA_MODE signal 193 is logic high, the output signal from comparator 111 at input 115c of AND gate 115 is gated off from reaching the input 120a of first logic circuit 120. A rising edge on either or both of the output signal from AND gate 115 or the OOA_TIMEOUT signal causes OR gate 116 to output a rising edge through the falling edge delay circuit 118 to the clock input 120a of first logic circuit 120.

Error amplifier 150 includes a transconductance amplifier 152, resistor R1, and capacitors C2 and C3. Transconductance amplifier 152 produces an output current proportional to the difference between voltages VFB and VREF. Resistor R1 is coupled in series with capacitor C3. Capacitor C2 is coupled in parallel with the series combination of resistor R1 and capacitor C3. Capacitor C2 and the series combination of resistor R1 and capacitor C3 are coupled between the output of transconductance amplifier 152 and ground. The output current from transconductance amplifier 152 charges capacitor C2 to voltage Vcomp.

The output of transconductance amplifier 152 is coupled to the off-timer input 160a. Off-timer circuit 160 includes transistors M2-M5, resistor R2, capacitor C4, current source circuits I2 and I3, and a Schmitt trigger 164. Current source circuit I2 is coupled to the drain of transistor M2, and resistor R2 is coupled between the source of transistor M2 and ground. The drain of transistor M2 is coupled to the gates of transistors M3 and M4. The sources of transistors M3 and M4 are coupled together and to a supply terminal. The drain of transistor M3 is coupled to the source of transistor M2. Transistor M5, current source I3 and capacitor C4 are coupled in parallel between the drain of transistor M4 and ground. The signal (e.g., voltage) on capacitor C4 is a V_toff signal 195 and is turned into a logic high or low signal (Toff signal 194) by Schmitt trigger 164.

If the output voltage VOUT rises, the voltage VFB also rises, and the voltage Vcomp decreases. Transistor M2 is configured as a source follower and, accordingly, the voltage across resistor R2 decreases as well. A smaller voltage across resistor R2 causes the current through resistor R2 to decrease. Transistors M3 and M4 are configured as a current mirror. The current through transistor M4 decreases as the current through transistor M3 and resistor R2 decreases. A smaller current through resistor M4 causes capacitor C4 to be charged with a smaller current thereby causing the V_toff signal 195 to increase at a smaller rate. As a result of the V_toff signal rising at a smaller rate, the rising edge of the Toff signal 194 is delayed. By contrast, a reduction in voltage VFB causes the rising edge of the Toff signal 194 to occur earlier. Accordingly, the timing of when the rising edge of the Toff signal occurs is based on the magnitude of the output voltage VOUT.

Second logic circuit 148 includes an OR gate 144 having inputs 144a and 144b and an AND gate 146 having inputs 146a and 146b. Inputs 144a and 144b are coupled logic circuit control inputs 148b and 148c, respectively. The output of OR gate 144 is coupled to the input 146b of AND gate 146, and the input 146a of AND gate 146 is coupled to the logic circuit control input 148a. Accordingly, OR gate 144 logically ORs the signal from the OOA output 170f with the signal form inverter 142. AND gate 146 logically ANDs the signal from the logic circuit control output 120d with the signal from the output of OR gate 144. The output of AND gate 146 is coupled to the input 134a of minimum on-time control circuit 134. A logic high signal level from the output of AND gate 146 causes the LS switch to turn on. The logic circuit control output 120c is coupled to the input 132a of minimum on-time control circuit 132. A logic high signal level from the logic circuit control output 120c causes the HS switch to turn on.

OOA circuit 170 includes a comparator 171, a timer 172, a set-reset (SR) latch 173, and AND gates 174 and 176. The voltage VFB is provided to the negative input of comparator 171, and a reference voltage VREF_OOA (which may be the same as or different from reference voltage VREF) is provided to the positive input of comparator 171. Reference voltage VREF_OOA may be generated by a reference voltage circuit. The output 171a of comparator 171 is coupled to an input 176a of AND gate 176. The Q output of SR latch 173 is coupled to the input 176b of AND gate 176. Comparator 140 generates a ZERO_CROSS signal 191 at its output 140a which is coupled to OOA input 170a and to an enable (EN) input of timer 172. The output 118b of falling edge delay circuit 118 is coupled to the OOA input 170b of OOA circuit 170. Accordingly, the clock signal Clock is provided to a reset (RST) input of timer 172. Timer 172 generates the OOA_TIMEOUT signal 192 at a timer output 172a, which is coupled to the OOA output 170e and to a set(S) input of SR latch 173. The output of AND gate 176 is coupled to the reset (R) input of SR latch 173. SR latch 173 generates the OOA_MODE signal 193 at its Q output, which is coupled to an input 174a of AND gate 174. The off-timer output 160b is coupled to the OOA input 170c of OOA circuit 170 and to an input 174b of AND gate 174. The output of AND gate 174 is coupled to logic circuit control input 148b and to input 144a of OR gate 144.

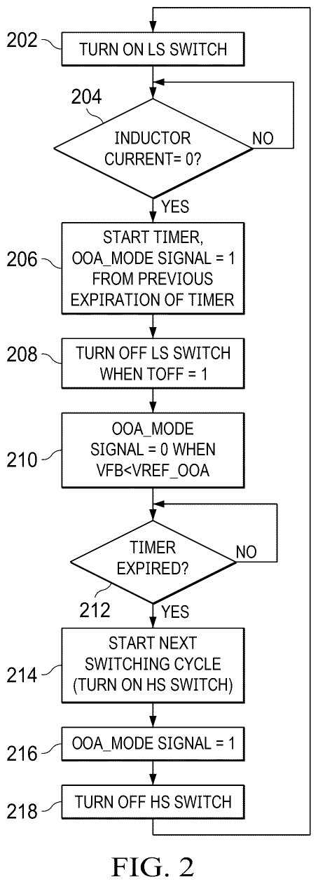

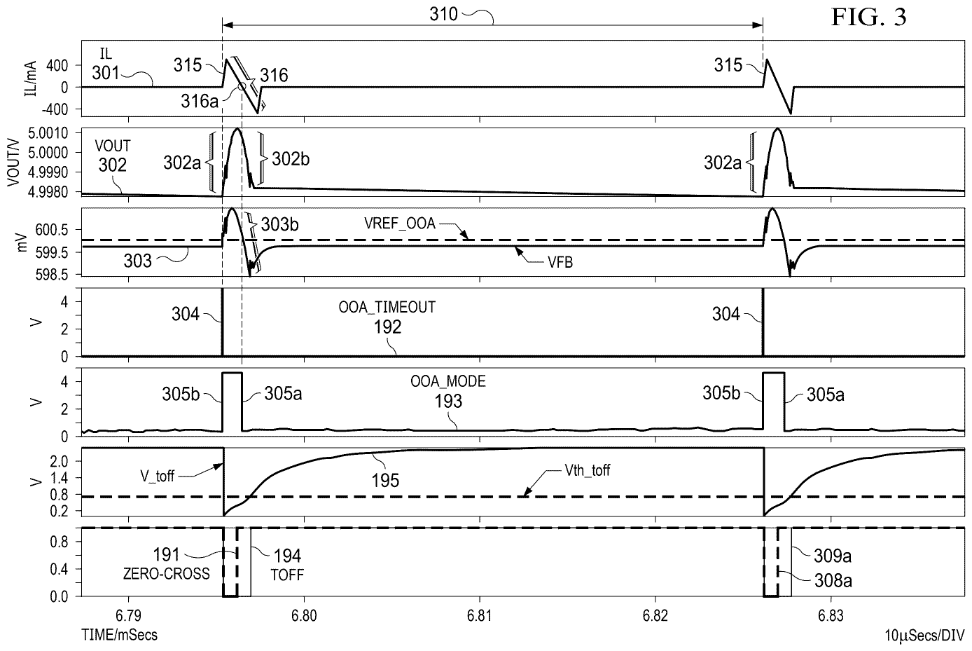

The operation of power converter 100 is explained with reference to the flowchart of FIG. 2 and example waveforms of FIG. 3. The operations illustrated in the flowchart of FIG. 2 represent at least some of the operations performed during each switching cycle of power converter 100 while the power converter is operating in a discontinuous current mode (DCM). The DCM is a mode of operation in which the current IL through inductor L1 drops to zero amperes and remains at zero amperes until the next PWM signal pulse. DCM operation may occur when the load is small. During each switching cycle during DCM operation, the HS switch turns on, then the LS turns on, and then neither the HS nor the LS switch is on for the remainder of the switching cycle. The waveforms illustrated in FIG. 3 include inductor current 301, output voltage VOUT 302, voltage VFB, the OOA_TIMEOUT signal 192, the OOA_MODE signal 193, the V_toff signal 306, the ZERO_CROSS signal 191, and the Toff signal 194.

The flowchart of FIG. 2 is circular in nature meaning that the process depicted therein is a continuous loop. The first operation discussed below is operation 202 in which the HS switch had been on and now first logic circuit 120 is turning on the LS switch. First logic circuit 120 asserts a short positive pulse at its logic circuit control output 120d. With the LS switch on, the inductor current IL decreases, as indicated at 316. The output voltage VOUT and the voltage VFB also decrease as indicated at 302b. and 303b, respectively. When inductor current IL reaches a minimum current level (e.g., 0 amperes) as indicated at 316a as determined by decision operation 204 (the “y” branch), comparator 140 forces its output ZERO_CROSS signal 191 to a logic high state (rising edge 308a), which causes the output signal from inverter 142 to become logic low.

Two actions occur in response to the ZERO_CROSS signal 191 being logic high. First, at operation 206 a rising edge (or logic high state) of the ZERO_CROSS signal 191 at the enable input of timer 172 causes timer 172 to begin counting an internal clock within the timer. Timer 172 determines whether the minimum (e.g., zero-ampere) inductor current state during DCM operation has persisted long enough that the switching frequency of power converter 100 is at risk for being low enough to cause an audible tone (e.g., produced by capacitor C1 as described above). In one example, the period of time for which timer 172 counts is preset within timer 172. In an example, the time period for which timer 172 counts is between 25 microseconds and 35 microseconds. At the moment that timer 172 is enabled, the OOA_MODE signal 193 is at a logic ‘1’ from the previous expiration of the timer.

Second, at operation 208, the LS switch is turned off when the Toff signal 194 at the inverted input of AND gate 174 becomes a logic ‘1.’ Because the ZERO_CROSS signal is logic high, inverter 142 forces its output signal to a logic low level. The output of AND gate 174 is also at a logic low level when the Toff signal becomes a logic high. Accordingly, the output of OR gate 144 is a logic low signal. The signal from logic circuit control output 120d to initially turn on the LS transistor was a short duration positive pulse. When the ZERO_CROSS signal becomes logic high, the signal from logic circuit control output 120d has returned to a logic low level. Accordingly, the output signal from AND gate 146 is logic low, which causes the LS switch to turn off.

With both the HS and LS switches off, current to load RL is supplied by capacitor C1, thereby causing capacitor C1 to at least partially discharge. While capacitor C1 discharges, output voltage VOUT continues decreasing 302b. Accordingly, the voltage VFB also continues decreasing. In response to voltage VFB falling below reference voltage VREF_OOA, comparator 171 generates a logic high signal at its output to AND gate 176. With the OOA_MODE 193 signal still logic high, the output signal from AND gate 176 becomes logic high thereby resetting the SR latch 173 and forcing the OOA_MODE signal output by SR latch 173 to a logic low state (operation 210), as indicated by falling edge 305a.

Decision operation 212 determines whether timer 172 has expired. When timer 172 expires (the ‘Y’ branch), the timer's outputs OOA_TIMEOUT signal 192 pulses logic high (304). With the OOA_TIMEOUT signal being logic high, through OR gate 116 in clock generation circuit 110, first logic circuit 120 receives a rising edge of clock signal Clock and initiates the next switching cycle at operation 214. The next switching cycle includes first logic circuit 120 turning on the HS switch by generating a positive pulse at logic circuit control output 120c. With the HS switch being on, the inductor current IL rises, as indicated at 315. The output voltage VOUT and voltage VFB also rise as indicated by 302a and 303a, the OOA_TIMEOUT signal 192 being logic high sets the SR latch 173 thereby forcing the OOA_MODE signal 193 back to a logic high state (rising edge 305b).

At operation 218, first logic circuit 120 responds to a logic high HS_OFF signal from comparator 154 (which occurs when the signal from current sense circuit 136 exceeds the signal Vcomp from error amplifier 150) by turning off the HS switch. After a blanking period (implemented by first logic circuit 120 to ensure both the HS and LS switches are not on at the same time), control returns to operation 202 and the process repeats.

A technical advantage of the example OOA circuit 170 in FIG. 1 is that the expiration of timer 172 triggers the start of the next switching cycle in which the inductor current rises (315) before the LS switch turns on, which causes the inductor current to decrease (316). As a result of this behavior, the output voltage experiences a small increase as shown at 302a before it quickly returns to its target level. Accordingly, power converter 100 does not experience a loss of regulation for multiple switching cycles as might otherwise be the case conventional OOA circuits. For example, in a conventional OOA circuit, such a circuit may respond to an expiration of a timer by first turning on the LS switch before allowing the control mechanism of the control circuitry to initiate a new switching cycle. This type of OOA circuit may cause a loss of regulation that spans multiple switching cycles. The OOA circuit 170 described herein advantageously avoids such a loss of regulation.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “ON” or “enabled” means that the conduction channel of the FET is present and drain current may flow through the FET. References herein to a FET being “OFF” or “disabled” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

What is claimed is:

1. An apparatus, comprising:
a logic circuit having a clock input, a first logic circuit control output, and a second logic circuit control output;
a clock generation circuit having a first clock control input, a second clock control input, and a clock output, the clock output coupled to the clock input;
an off-timer circuit having an off-timer output;
a comparator having a comparator output; and
an out-of-audio (OOA) circuit having a first OOA input, a second OOA input, a third OOA input, a first OOA output, and a second OOA output, the first OOA input coupled to the comparator output, the second OOA input coupled to the clock output, the third OOA input coupled to the off-timer output, the first OOA output coupled to the first clock control input, and the second OOA output coupled to the second clock control input.

2. The apparatus of claim 1, wherein the OOA circuit includes a timer having an output, the output of the timer coupled to the second OOA output.

3. The apparatus of claim 2, wherein the timer is configured to determine when an output current has been at minimum current level for between 25 microsecond and 35 microseconds.

4. The apparatus of claim 2, further comprising:
a logic gate having first logic gate input and a second logic gate input; and
a latch having a first latch input and latch output, the first latch input coupled to the output of the timer, and the latch output coupled to the first logic gate input.

5. The apparatus of claim 4, wherein the logic gate includes an AND gate.

6. The apparatus of claim 4, wherein the comparator is a first comparator, the comparator output is a first comparator output, and the logic gate is a first logic gate, and the apparatus further comprises:
a second logic gate having third logic gate input, a second logic gate input, and a logic gate output, the second logic gate input coupled to the first OOA output; and
a second comparator having a first comparator input, a second comparator input, and a second comparator output, the second comparator output coupled to the third logic gate input.

7. The apparatus of claim 6, wherein the latch has a second latch input, and the logic gate output is coupled to the second latch input.

8. The apparatus of claim 1, wherein the clock generation circuit includes:
a clock circuit having an output; and
a logic gate circuit having a first input, second input, and a third input, the first input of the logic gate circuit coupled to the first clock control input, the second input of the logic gate circuit coupled to the second clock control input, the third input of the logic gate circuit coupled to the output of the clock circuit.

9. The apparatus of claim 8, wherein the logic gate circuit includes:
an AND gate having a first input coupled to the first input of the logic gate circuit, having a second input coupled to the third input of the logic gate circuit, and having an output; and
an OR gate having a first input coupled to the output of the AND gate, having a second input coupled to the second input of the logic gate circuit, and having an output coupled to the clock output.

10. An apparatus, comprising:
a logic circuit having a clock input, a first logic circuit control output, and a second logic circuit control output;
a clock generation circuit having a clock output, a first clock control input, and a second clock control input the clock output coupled to the clock input;
an off-timer circuit having an off-timer output;
a comparator having a comparator output; and
an out-of-audio (OOA) circuit coupled to the comparator output, the clock output, the first clock control input, the second clock control input, and the off-timer output, the OOA circuit configured to start a timer based on a comparator signal from the comparator output and to cause the logic circuit to initiate a switching cycle outside an audible frequency range, wherein initiation the switching cycle is based on expiration of the timer.

11. The apparatus of claim 10, wherein the logic circuit is a first logic circuit and the OOA circuit has an output, and the apparatus further comprises:
a second logic circuit having a third logic circuit control input, a fourth logic circuit control input, a fifth logic circuit control input, and an output, the third logic circuit control input coupled to the second logic circuit control output, the fourth logic circuit control input coupled to an output of the OOA circuit, and the fifth logic circuit control input coupled to the comparator output; and
wherein, until a first signal at the off-timer output is at a first logic state, the OOA circuit is configured to cause the second logic circuit to assert a second signal at the output of the second logic circuit regardless of a logic state of a signal at the comparator output.

12. The apparatus of claim 10, wherein the OOA circuit includes a latch, and wherein the OOA circuit is configured to set the latch responsive to expiration of the timer.

13. The apparatus of claim 12, wherein the OOA circuit is configured to reset the latch responsive to a voltage being below a reference voltage.

14. The apparatus of claim 12, wherein the latch has a reset input and the OOA circuit includes:
a comparator having an output; and
a logic gate having a first input coupled to the output of the comparator and having an output coupled to the reset input.

15. The apparatus of claim 14, wherein the logic gate has a second input and the latch has an output coupled to the second input of the latch.

16. A power converter, comprising:
a power stage having a first power stage input and a second power stage input;
a logic circuit having a clock input, a first logic circuit control output, and a second logic circuit control output, the first logic circuit control output coupled to the first power stage input, and the second logic circuit control output coupled to the second power stage input;
a clock generation circuit having a clock output, a first clock control input, and a second clock control input the clock output coupled to the clock input;
an off-timer circuit having an off-timer output;
a comparator having a comparator output; and
an out-of-audio (OOA) circuit coupled to the comparator output, the clock output, the first clock control input, the second clock control input, and the off-timer output, the OOA circuit configured to start an OOA circuit timer based on a comparator signal from the comparator output and to cause the logic circuit to initiate a switching cycle upon expiration of the OOA circuit timer.

17. The power converter of claim 16, wherein the power converter is a buck converter.

18. The power converter of claim 16, wherein:
the power stage has a first transistor coupled in series with a second transistor between a first voltage terminal and a second voltage terminal, the second transistor having a control input;
the OOA circuit timer has an output;
the OOA circuit includes a latch having a first input, a second input, and a latch output, the first input of the latch coupled to the output of the OOA circuit timer; and
the OOA circuit is configured to cause the second transistor to turn off in response to a signal at the off-timer output being a first logic state while the latch output is at a first logic state, the first logic state indicative of expiration of the OOA circuit timer.

19. The power converter of claim 18, further comprising a minimum on-time circuit coupled between the second logic circuit control output and the control input of the second transistor.

20. The power converter of claim 16, wherein power converter has a switching frequency, and the OOA circuit is configured cause the switching frequency to be above approximately 20 KHz.
